(19) United States
(12) Patent Application Publication
(10) Pub. No.: US 2026/0122927 A1
(43) Pub. Date: Apr. 30, 2026

(54) GRADED THIN FILM RESISTOR

(71) Applicant: Taiwan Semiconductor Manufacturing Company, Ltd., Hsinchu (TW)

(72) Inventors: Chun-Heng CHEN, Hsinchu City (TW); Hsin-Li Cheng, Hsinchu (TW); Ru-Shang Hsiao, Jhubei (TW); Shih-Fen Huang, Jhubei (TW); Tuo-Hsin Chien, Hsinchu County (TW); Yu-Wei Liang, Kaohsiung City (TW)

(73) Assignee: Taiwan Semiconductor Manufacturing Company, Ltd., Hsinchu (TW)

(21) Appl. No.: 18/929,574

(22) Filed: Oct. 28, 2024

(51) Int. Cl. H10D 1/47

(52) U.S. Cl. CPC H10D 1/474

(57) ABSTRACT

A semiconductor device including a thin film resistor and a method of fabricating the same are disclosed. The method includes forming, within a first metallization layer, a silicon chromium-based thin film resistor including sub-layers with different silicon chromium compositions, forming contact regions on ends of the silicon chromium based thin film resistor and on contact structures. The method further includes forming, on the first metallization layer, a second metallization layer including other contact structures in contact with the contact structures.

### BACKGROUND

An integrated circuit (IC) can include thin film resistors. A thin film resistor is characterized by properties such as sheet resistance and temperature coefficient of resistance, which is a change in resistance of the thin film resistor with a change in temperature. A thin film resistor's properties can be affected by elevated temperatures during IC processing operations subsequent to formation of the thin film resistor. Therefore, it is important to design a thin film resistor that is compatible with IC processing operations.

### BRIEF DESCRIPTION OF THE DRAWINGS

Aspects of this disclosure are best understood from the following detailed description when read with the accompanying figures.

FIG. 1 illustrates a cross-sectional view of a semiconductor device with a thin film resistor, in accordance with some embodiments.

FIG. 2 is a flow diagram of a method for fabricating a semiconductor device with a thin film resistor, in accordance with some embodiments.

FIGS. 3A, 4A-6A, 4B-6B, and 7-12 illustrate cross-sectional views of a semiconductor device with a thin film resistor at various stages of its fabrication process, in accordance with some embodiments.

FIGS. 3B-3H illustrate composition profiles of a thin film resistor layer, in accordance with some embodiments.

FIG. 3I illustrates a variation in temperature coefficient of resistance and sheet resistance of a silicon chromium (SiCr) based thin film resistor layer with different SiCr compositions, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

Temperature coefficient of resistance (TCR) is a measure of a change in a film's sheet resistance due to a change in temperature. Zero temperature coefficient of resistance (TCR) is a preferred property for a thin film resistor (TFR). TFRs with zero or near-zero TCR can be used in electronic circuits exposed to extreme environments and extreme processing conditions. Chromium-based materials, such as silicon chromium (SiCr), can be used for thin film resistors due to their near-zero TCR and high sheet resistance (Rs). These materials can be integrated with complementary metal oxide semiconductor (CMOS) process flows. Integration of fabrication of a thin film resistor with the CMOS process flow subjects a thin film resistor layer of the TFR to subsequent processes, such as etching, oxidation, and thermal annealing, which can alter a composition of the thin film resistor layer. An alteration in composition or a composition drift can lead to a TCR deviation from a desired value as well as sheet resistance degradation. The composition drift can further narrow a reliability margin for electro-migration.

Embodiments of the present disclosure are directed to a TFR using a SiCr thin film resistor layer. For example, a TFR using a uniform SiCr layer as a thin film resistor layer can be subjected to film damage, thinning, crystallization, and/or composition drift during process operations of the CMOS process flow, subsequent to formation of the SiCr layer. Subsequent CMOS processes, such as etching, oxidation, and thermal annealing, can result in element loss or extra oxygen incorporation into the SiCr layer causing the Si: Cr ratio to deviate from the as-deposited ratio. A deviation in the Si: Cr ratio can result in a non-uniform SiCr film. Consequently, the TCR value of the SiCr film can drift and the sheet resistance can be degraded.

To address these challenges, the present disclosure provides a semiconductor device that includes a TFR that can mitigate deviation of TCR and Rs during fabrication process integration of the TFR with the CMOS fabrication process. The present disclosure also provides an example method for fabricating the same. The TFR can include a chromium-based resistor layer. For example, the chromium-based resistor layer can be SiCr. Rather than fabricating a SiCr layer with a uniform Si:Cr ratio across its entire thickness, the SiCr layer can have a composition gradient along its thickness. A SiCr layer with a composition gradient can be formed of sub-layers with varying SiCr compositions and is therefore also referred to herein as “graded SiCr layer.” An as-deposited graded SiCr layer, can, after being exposed to subsequent CMOS processing operations, develop a uniform Si:Cr ratio or a uniform SiCr composition. The sub-layers forming the graded SiCr layer can have (a) a placement along the thickness of the SiCr layer suited to withstand an impact of the CMOS process operation which can be etching, oxidation, thermal annealing, or other operations, and (b) an optimized Si:Cr ratio which after being influenced by the CMOS process operations mentioned above can result in a uniform Si:Cr ratio or a uniform SiCr composition.

A graded SiCr layer also addresses other challenges associated with integration of the SiCr TFR fabrication with the CMOS process flow. For example, etching and deposition processes within the CMOS process flow affect a top surface and/or a bottom surface of the SiCr layer. The top and bottom surfaces can undergo thinning, crystallization, damage, composition drift including element loss or extra oxygen incorporation which can cause the Si:Cr ratio to shift from the as-deposited ratio. A graded SiCr layer with bottom-most and/or uppermost sub-layers with a different Si:Cr ratio than the middle sub-layers (also referred to herein as “bulk SiCr sub-layers”) can mitigate the impact of etching and deposition processes. For example, a SiCr layer with an uppermost sub-layer rich in Cr can protect the bulk SiCr sub-layers during a capping layer deposition subsequent to formation of the thin film resistor layer in the TFR fabrication process. As another example, an uppermost sub-layer rich in Cr can also act as an etch stop layer during dry-etching of the capping layer to form contact pads as Cr can have a high etch resistance and high hardness. A SiCr layer with an upper-most sub-layer rich in Si can oxidize to form a silicon oxide (SiO) based passivation layer to prevent oxidation of silicon in the bulk SiCr sub-layers during subsequent inter-layer dielectric (ILD) deposition. In another example, a SiCr layer with a bottom-most sub-layer rich in Si can retard oxygen ingress from an underlying ILD layer into the bulk SiCr sub-layers. This can prevent subsequent SiCr layer delamination from the underlying ILD layer. The SiCr sub-layers can be Si-rich or Cr-rich. In reference to the present disclosure, a Si-rich SiCr sub-layer can include a greater percentage of Si compared to Cr. For example, a Si-rich sub-layer can include between about 51 atomic % to about 100 atomic % of Si, and between about 49 atomic % to about 0 atomic % of Cr. On the other hand, a Cr-rich SiCr sub-layer can include a greater percentage of Cr compared to Si. For example, a Cr-rich sub-layer can include about 51 atomic % to about 100 atomic % of Cr, and about 49 atomic % to about 0 atomic % of Si.

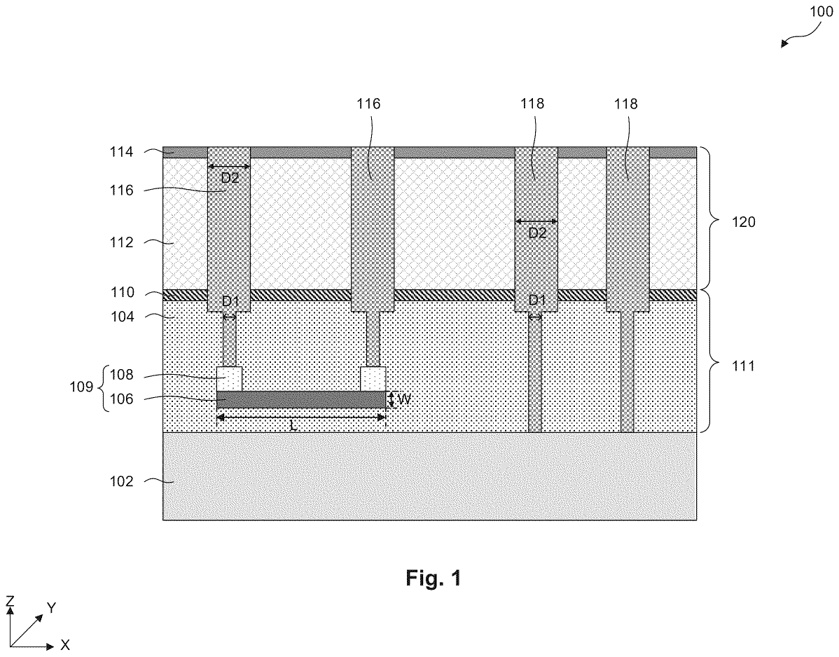

FIG. 1 illustrates a cross-sectional view of a semiconductor device 100 with a TFR 109, according to some embodiments of the present disclosure. Though semiconductor device 100 is shown to have one TFR 109, semiconductor device 100 can have any number of TFRs.

Semiconductor device 100 can include substrate 102, a first metallization layer 111, and second metallization layer 120. First metallization layer 111 can include (i) interlayer dielectric (ILD) layer 104 disposed on substrate 102, (ii) thin film resistor layer 106 embedded within ILD layer 104, (iii) at least two contact regions 108 disposed on thin film resistor layer 106, (iv) lower portions of interconnect structures 116 electrically connected to contact regions 108, (v) first etch stop layer (ESL) 110 disposed on ILD layer 104 and surrounding interconnect structures 116 and interconnect structures 118, and (vi) lower portions of interconnect structures 118 surrounded by ILD layer 104. Second metallization layer 120 can includes (i) ILD layer 112 disposed on first ESL layer 110, (ii) second ESL layer 114 disposed on ILD layer 112, (iii) an upper portion of interconnect structures 116 surrounded by ILD layer 112 and second ESL layer 114, and (iv) an upper portion of interconnect structures 118 surrounded by ILD layer 112 and second ESL layer 114. Interconnect structures 118 can contact logic areas of logic circuits in/on substrate 102.

TFR 109 formed of thin film resistor layer 106 and contact regions 108 can be surrounded by ILD layer 104. Contact regions 108 are electrically coupled to thin film resistor layer 106 and form the input and output connections for TFR 109. Contact regions 108 are disposed above thin film resistor layer 106. Each contact region 108 is connected to interconnect structure 116.

As illustrated in FIG. 1, TFR 109 is further connected to interconnect structures 116 formed within first metallization layer 111 and second metallization layer 120. According to various embodiments of the present disclosure, second metallization layer 120 is disposed on first metallization layer 111 and separated by first ESL layer 110 of first metallization layer 111. Interconnect structures 116 connect TFR 109 to (a) other interconnect pads (not shown) that can be disposed on second metallization layer 120 or (b) other interconnect structures disposed on second metallization layer 120. ILD layer 112 forming second metallization layer 120 provides electrical isolation between interconnect structures 116 and 118. Interconnect structures 118 connect substrate 102 to (a) other interconnect pads (not shown) that can be disposed on second metallization layer 120 or (b) other interconnect structures disposed on second metallization layer 120. In some embodiments, metallization layer 111 can be a first BEOL layer of a stack of BEOL metallization layers or any BEOL layer within a stack of BEOL metallization layers disposed on substrate 102. In some embodiments, metallization layer 111 can be electrically coupled to underlying metallization layers (e.g., MEOL and/or BEOL metallization layers) or devices within substrate 102. For example, interconnect structures 118 can be in contact with respective interconnect structures of underlying metallization layers (e.g., MEOL and/or BEOL metallization layers) or devices. The aforementioned layers and features within substrate 102, which are not shown in FIG. 1, are within the spirit and the scope of this disclosure.

Substrate 102 can be a semiconductor material, such as silicon (Si), germanium (Ge), silicon germanium (SiGe), a silicon-on-insulator (SOI) structure, other suitable semiconductor materials, and a combination thereof. Further, substrate 102 can be doped with p-type dopants (e.g., boron, indium, aluminum, or gallium) or n-type dopants (e.g., phosphorus or arsenic). In some embodiments, substrate 102 can be a III-V compound, such as gallium-arsenide (GaAs), gallium-phosphide (GaP), indium-phosphide (InP), indium arsenide (InAs), other suitable III-V compounds, and a combination thereof. In some embodiments, substrate 102 can be a back-end-of-line (BEOL) metallization layer, which includes conductive vias forming connections within and between other metallization layers above and below itself. In some embodiments, substrate 102 can be a partially fabricated wafer with one or more layers formed thereon. These one or more layers, which are not shown in FIG. 1 for simplicity, can include, for example, front-end-line (FEOL) structures (e.g., active devices, passive devices, doped regions, epitaxial structures, etc.) and interconnect layers (e.g., middle-of-line (MEOL) metallization layers, BEOL metallization layers, or combinations thereof).

In some embodiments, ILD layer 104 can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOₓ), and any other suitable insulating material. In some embodiments, ILD layer 104 can include low-k materials. Low-k refers to a dielectric constant that is less than the dielectric constant of SiO₂ (e.g., less than 3.9). For example, materials such as undoped silica glass (USG), phosphor doped silicate glass (PSG), fluorine doped silicate glass (FSG), boron doped silicate glass (BSG), or a boron phosphorous doped silicate glass (BSPG) can be used. In some embodiments, ILD layer 104 can include porous or non-porous carbon doped SiO₂ (black diamond).

Thin film resistor layer 106 (also referred to herein as “SiCr layer 106” or “graded SiCr layer 106”) can include chromium-based resistor materials, such as SiCr, nickel chromium (NiCr), Cr—SiO, Crₓ—Si_{y}N_{z}, or a combination thereof. SiCr layer 106 can have sub-layers with different Si:Cr ratios. Based on the area of application and CMOS integration requirements, graded SiCr layer 106 can have two or more sub-layers with different Si:Cr ratios. Thin film resistor layer 106 forming TFR 109 can have a length L along a x-direction and a thickness W along the z-direction. In some embodiments, thickness W of SiCr layer 106 of TFR 109 can be between about 0.6 μm and about 25 μm. Length L of thin film resistor layer 106 forming TFR 109 can be between about 2 μm and about 50 μm. TFR can have a L:W ratio greater than 1 (L/W>1).

In some embodiments, TFR 109 can further include contact regions 108 formed of materials such as titanium nitride (TiN), titanium tungsten (TiW), tantalum nitride (TaN), tantalum tungsten (TaW), or tantalum tungsten (TaN). In some embodiments, contact regions 108 can have a thickness, such as from about 50 angstroms to about 1000 angstroms in a direction perpendicular to substrate 102. Contact regions 108 are electrically coupled to TFR 109.

According to some embodiments, first ESL layer 110 can be formed of a material that has a high etching selectivity to the overlying second dielectric layer 112, so that ESL 110 can be used to stop the etching of ILD layer 112. First ESL 110 can include a metal nitride, a metal carbide, a metal oxide, or the like, where the metal can include aluminum (Al), manganese (Mn), copper (Cu), or multilayers thereof. In some embodiments, ESL 110 can include silicon nitride (SiₓN_{y}), silicon carbide (SiC), silicon carbon nitride (SiCN), silicon oxynitride (SiON), or a combination thereof. ILD layer 112 can be formed of materials similar to materials used to form ILD layer 104, according to some embodiments. Second ESL layer 114 disposed on ILD layer 112 can act as a hard mask layer during formation of interconnect structures 116. Second ESL 114 can be formed of materials similar to those used to form first ESL 110. Interconnect structures 116 can be disposed within ILD layer 104 and ILD layer 112. Each contact region 108 is electrically connected to one of interconnect structures 116. Interconnect structures 116 can be formed of a conductive material. The conductive material can include tungsten (W), copper (Cu), AlCu, or a combination thereof. In some embodiments, the conductive material can include cobalt (Co), ruthenium (Ru), iridium (Ir), nickel (Ni), osmium (Os), rhodium (Rh), aluminum (Al), molybdenum (Mo), zirconium (Zr), stannum (Sn), silver (Ag), gold (Au), zinc (Zn), cadmium (Cd), any other suitable conductive material, and a combination thereof. In some embodiments, interconnect structures 116 can include a liner layer (not shown), where the conductive material is disposed on the liner layer. In some embodiments, the liner layer can include nickel silicide (NiSi), tungsten silicide (WSi2), titanium silicide (TiSi2), cobalt silicide (CoSi2), or other suitable metal silicides.

ILD layer 104 and ILD layer 112 can have interconnect structures 118 connected to substrate 102. As disclosed above, in some embodiments, substrate 102 can be a metallization layer with conductive vias forming connections within and between metallization layers above and below itself. In such embodiments, interconnect structures 118 can provide an electrical connection to conductive vias within substrate 102. In some embodiments, substrate 102 can be a backend-of-line (BEOL) layer within a stack of BEOL metallization layers or a middle-of-line (MEOL) layer. In some embodiments, substrate 102 can be a front-end-of-line (FEOL) layer with active and/or passive devices. The aforementioned layers and features within substrate 102, which are not shown in FIG. 1, are within the spirit and the scope of this disclosure.

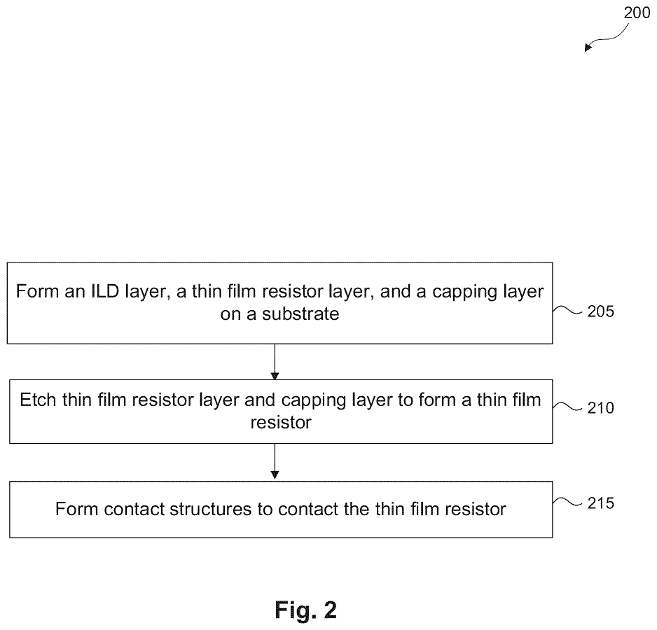

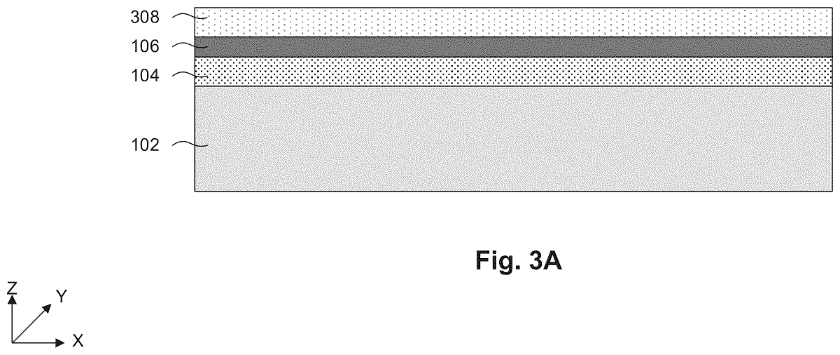

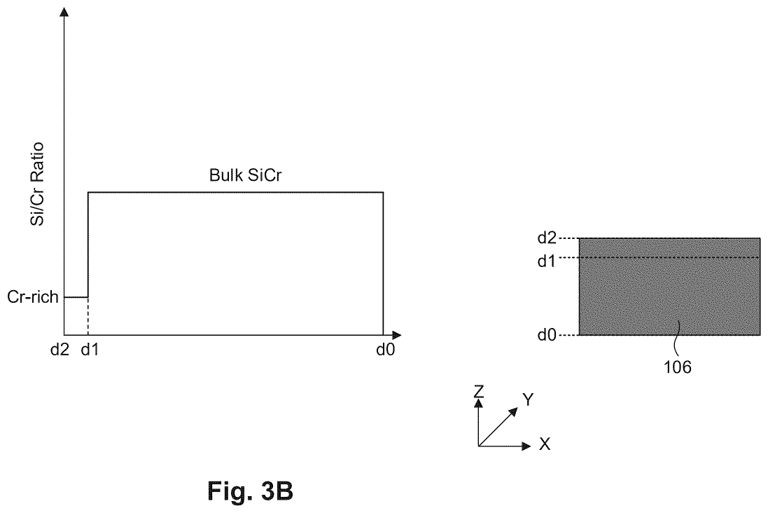

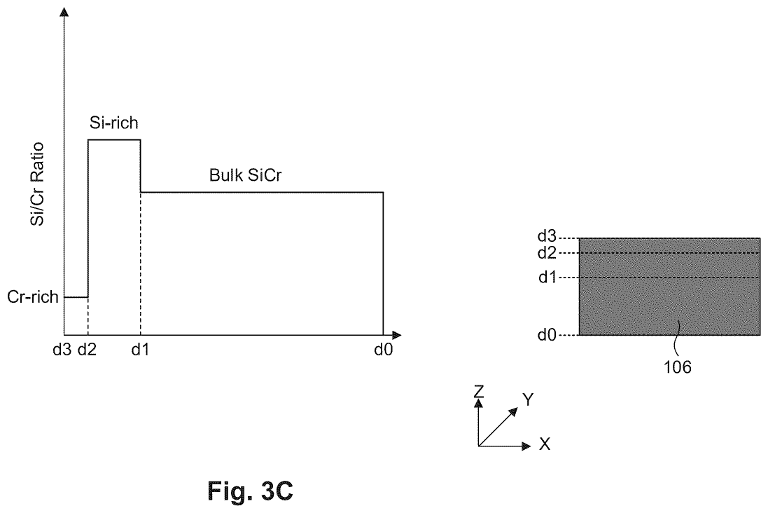

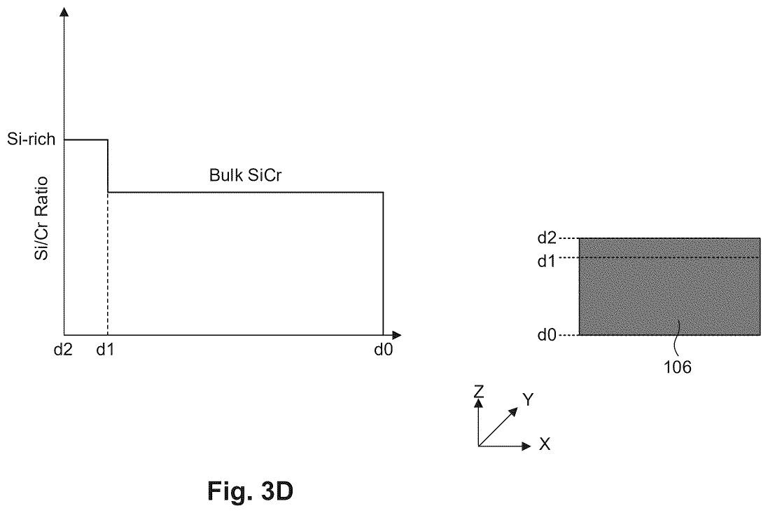

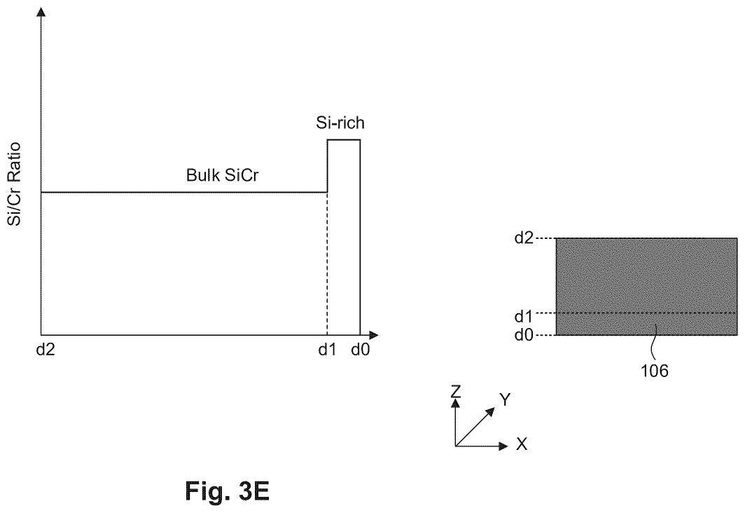

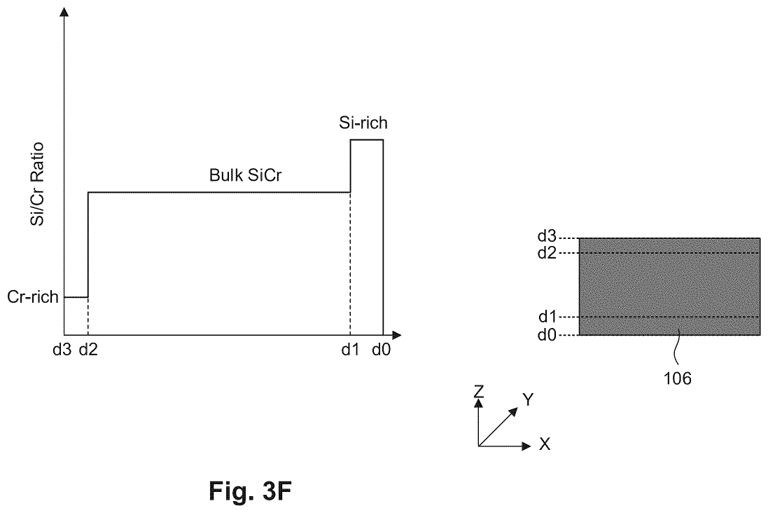

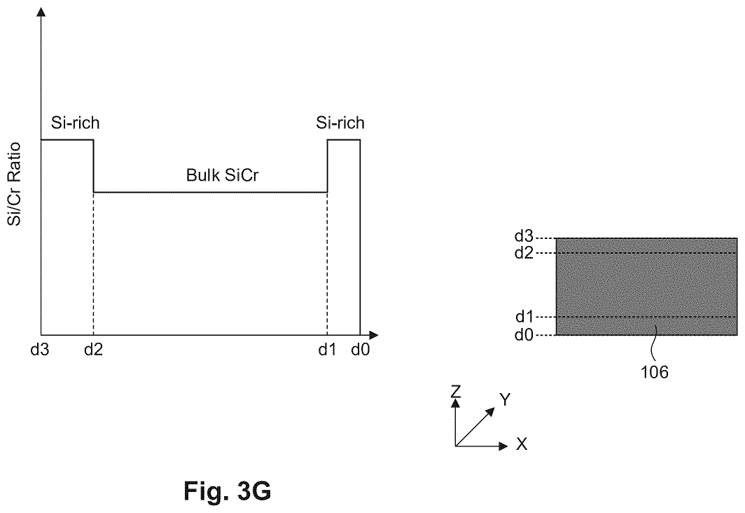

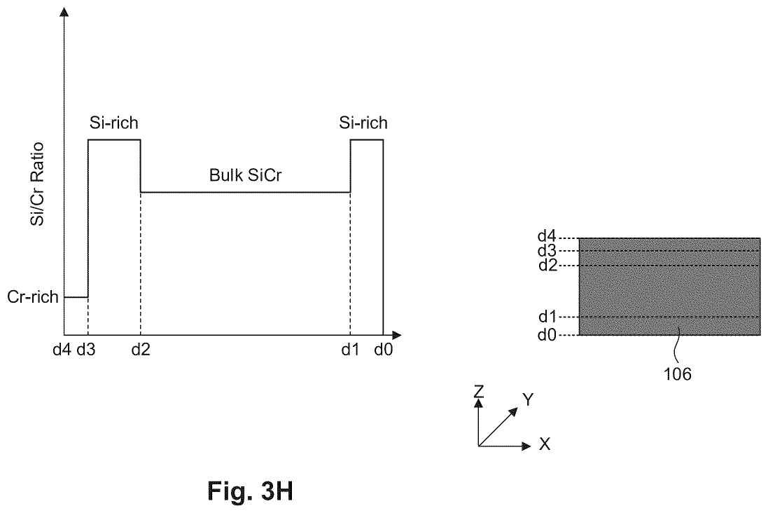

FIG. 2 is a flow diagram of an example method 200 for fabricating semiconductor device 100 as shown in FIG. 1, according to some embodiments. For illustrative purposes, the operations illustrated in FIG. 2 will be described with reference to the example fabrication process for fabricating semiconductor device 100 as illustrated in FIGS. 3A, 4A-6A, 4B-6B, 4C-6C, and 7-12, and SiCr layer composition profiles as illustrated in FIGS. 3B-3H. Operations can be performed in a different order or not performed depending on specific applications. It should be noted that method 200 may not produce a complete semiconductor device 100. Accordingly, it is understood that additional processes can be provided before, during, and after method 200, and that some other processes may only be briefly described herein. Elements in FIGS. 3A, 4A-6A, 4B-6B, 4C-6C, and 7-12 with the same annotations as elements in FIG. 1 are described above.

Referring to operation 205, an ILD layer, a thin film resistor layer and a capping layer are deposited on a substrate. For example, as shown in FIG. 3A, ILD layer 104 can be deposited on substrate 102. ILD layer 102 can be deposited by a process, such as chemical vapor deposition (CVD), physical vapor deposition (PVD), high density plasma chemical vapor deposition (HDPCVD), metal organic chemical vapor deposition (MOCVD), remote plasma chemical vapor deposition (RPCVD), plasma enhanced chemical vapor deposition (PECVD), pulsed laser deposition (PLD), atomic layer deposition (ALD), any other suitable process, or a combination thereof.

Subsequently, thin film resistor layer 106 can be deposited on ILD layer 104. Thin film resistor layer 106 can include silicon chromium (SiCr), nickel-chromium (NiCr), Cr—SiO, Crₓ—Si_{y}N_{z}, or a combination thereof. Thin film resistor layer 106 can be deposited by a process, such as CVD, PVD, HDPCVD, MOCVD, RPCVD, PECVD, PLD, ALD, any other suitable process, or a combination thereof. In some embodiments, SiCr layer 106 can be deposited using sputter deposition. In some embodiments, thin film resistor layer 106 (also referred to herein as “SiCr layer 106”) can be sputter deposited in multiple chambers of a sputtering cluster tool using multiple SiCr targets having different SiCr compositions. Substrate 102 can be transferred between multiple chambers of a sealed sputtering cluster tool, so that substrate 102 is transferred between chambers under vacuum or inert gas conditions. SiCr layer 106 can be deposited by sputtering Si-rich sub-layers, Cr-rich sub-layers, and bulk SiCr sub-layers in different chambers of the sputtering cluster tool. For example, for depositing a Si-rich sub-layer, substrate 102 can be transferred to a sputtering chamber of the sputtering cluster tool with a Si-rich SiCr target. After forming the Si-rich sub-layer, substrate 102 can be transferred to a sputtering chamber with a SiCr target with a bulk composition or a Cr-rich SiCr target depending on the preferred composition of thin film resistor layer 106.

In some embodiments, to obtain a composition gradient along a thickness (in a direction perpendicular to substrate 102) of thin film resistor layer 106, a combination of Si-rich and Cr-rich sub-layers can be deposited using co-sputtering. The method of co-sputtering thin film resistor layer 106 (SiCr layer 106) can include sputtering a Si target and a Cr target within a single chamber of a sputtering tool. The Si target and Cr target are disposed near to each other within a chamber of a sputtering apparatus. The chamber is maintained at a processing pressure between about 10⁻² mbar and about 10⁻³ mbar, such as about 3×10⁻³ bar. The Si and Cr targets are co-sputtered and a SiCr based thin film resistor layer can be deposited on substrate 102. During the co-sputtering process, a sputtering gas, such as argon, nitrogen, or a combination thereof, can be used. The ratio of Si:Cr in the deposited SiCr layer 106 can be adjusted by changing the power applied to the Si target and the Cr target. The power applied to the Si and Cr targets can be between about 100 W and about 1000 W, such as about 500 W. For depositing a Si-rich sub-layer, the power applied to the Si target can be between about 300 W and about 1000 W, and the power applied to the Cr target can be between about 100 W and about 500 W. On the other hand, for depositing a Cr rich sub-layer, the power applied to the Cr target can be between about 250 W and about 1000 W, and the power applied to the Si target can be between about 100 W and about 600 W. Based on deposition rates, Si-rich and Cr-rich sub-layers of thicknesses included in the embodiments shown in FIG. 3B-3H can be deposited using a timed deposition process. In some embodiments, a thickness of Si-rich and Cr-rich sub-layers can be measured in-situ.

FIGS. 3B-3H illustrate different SiCr compositions across a thickness of thin film resistor layer 106, according to some embodiments. SiCr composition refers to the different Si:Cr ratios in each of the sub-layers forming thin film resistor layer 106. Positions d1, d2, d3, and d4 shown in FIGS. 3B-3H are positions of upper surfaces of the sub-layers forming thin film resistor layer 106 in a direction perpendicular to the substrate (which is the z-direction in FIGS. 3B-3H). Position d0 is a position of a bottom surface of the thin film resistor layer 106 in contact with ILD layer 104, along the z-direction.

In some embodiments, as shown in FIG. 3B, thin film resistor layer 106 can have a Cr-rich sub-layer between positions d2 and d1, and a sub-layer with a bulk SiCr composition (also referred to herein as “bulk SiCr sub-layer”) below the Cr-rich sub-layer between positions d1 and d0. The Cr-rich sub-layer can include about 51 at. % to about 100 at. % Cr, such as about 75 at. %. Cr The Cr-rich sub-layer can have a thickness between about 5 Å and about 50 Å. The bulk SiCr sub-layer can include about 50 at. % Cr and about 50 at. % Si. In other words, the bulk SiCr sub-layer can have a Si:Cr ratio of 1:1 and a thickness less than about 200 Å.

According to the embodiment shown in FIG. 3B, forming thin film resistor layer 106 between positions d0 and d2 can include (i) a first co-sputtering operation for forming the bulk SiCr sub-layer on the ILD layer 104 between positions d0 and d1, and (ii) a second co-sputtering operation for forming the Cr-rich sub-layer between positions d1 and d2 on the bulk SiCr sub-layer. Positions d1 and d2 are positions of top surfaces of the bulk SiCr sub-layer and Cr-rich sub-layer, respectively, in the z-direction. In some embodiments, forming the bulk SiCr sub-layer between positions d0 and d1 during the first co-sputtering operation can include providing a substantially equal amount of power to the Si target and the Cr target. For example, the power provided to the Si target and the Cr target can be between about 100 W and about 1000 W. After forming a targeted thickness of the SiCr sub-layer, the first co-sputtering operation can end and the second co-sputtering operation can begin. In some embodiments, forming the Cr-rich sub-layer between d1 and d2 during the second co-sputtering operation can include applying a higher power to the Cr target compared to the Si target. For example, the power provided to the Cr target can be between about 250 W and about 1000 W and the power provided to the Si target can be between about 100 W and about 600 W. The first and second co-sputtering operations can be performed within the same sputtering chamber.

In some embodiments, as shown in FIG. 3C, thin film resistor layer 106 can have a Cr-rich sub-layer between positions d3 and d2, a Si-rich sub-layer under the Cr-rich sub-layer between positions d2 and d1, and a sub-layer with a bulk SiCr composition (also referred to herein as “bulk SiCr sub-layer”) under the Si-rich sub-layer between positions d1 and d0. The Cr-rich sub-layer can include about 51 at. % to about 100 at. % Cr, such as about 75 at. % Cr, and can have a thickness between about 5 Å and about 50 Å. The Si-rich sub-layer can include about 51 at. % to about 100 at. % Si, such as about 100 at. % Si, and can have a thickness between about 5 Å and about 40 Å. The bulk SiCr sub-layer can include about 50 at. % Cr and about 50 at. % Si. In other words, the bulk SiCr sub-layer can have a Si:Cr ratio of 1:1 and can have a thickness less than about 200 Å.

According to the embodiment shown in FIG. 3C, forming thin film resistor layer 106 between positions d0 and d3 can include (i) a first co-sputtering operation for forming the bulk SiCr sub-layer on ILD layer 104 between positions d0 and d1, (ii) a second co-sputtering operation for forming the Si-rich sub-layer on the bulk SiCr sub-layer between positions d1 and d2, and (iii) a third co-sputtering operation for forming the Cr-rich sub-layer on the Si-rich sub-layer between positions d2 and d3. Positions d1, d2 and d3 are positions of top surfaces of the bulk SiCr sub-layer, Si-rich sub-layer, and Cr-rich sub-layer, respectively, in the z-direction. In some embodiments, forming the bulk SiCr sub-layer between positions d0 and d1 during the first co-sputtering operation can include providing a substantially equal amount of power to the Si target and the Cr target. For example, the power provided to the Si target and the Cr target can be between about 100 W and about 1000 W. After forming a targeted thickness of the bulk SiCr sub-layer, the first co-sputtering operation can end and the second co-sputtering operation can begin. In some embodiments, forming the Si-rich sub-layer between positions d1 and d2 during the second co-sputtering operation can include applying a higher power to the Si target compared to the Cr target. For example, the power provided to the Si target can be between about 300 W and about 1000 W and the power provided to the Cr target can be between about 100 W and about 500 W. After forming a targeted thickness of the Si-rich sub-layer, the second co-sputtering operation can end and the third co-sputtering operation can begin. In some embodiments, forming the Cr-rich layer between d2 and d3 during the third co-sputtering operation can include applying a higher power to the Cr target compared to the Si target. For example, the power provided to the Cr target can be between about 250 W and about 1000 W and the power provided to the Si target can be between about 100 W and about 600 W. The first, second, and third co-sputtering operations can be performed within the same sputtering chamber.

In some embodiments, as shown in FIG. 3D, thin film resistor layer 106 can have a Si-rich sub-layer between positions d2 and d1, and a sub-layer with a bulk SiCr composition (also referred to herein as “bulk SiCr sub-layer”) under the Si-rich sub-layer between positions d1 and d0. The Si-rich sub-layer can include about 51 at. % to about 100 at. % Si, such as about 100 at. % Si, and can have a thickness between about 5 Å and about 40 Å. The bulk SiCr sub-layer can include about 50 at. % Cr and about 50 at. % Si. In other words, the bulk SiCr can have a Si:Cr ratio of 1:1 and a thickness less than 200 Å.

According to the embodiment shown in FIG. 3D, forming thin film resistor layer 106 between positions d0 and d2 can include (i) a first co-sputtering operation for forming the bulk SiCr sub-layer on ILD layer 104 between positions d0 and d1, and (ii) a second co-sputtering operation for forming the Si-rich sub-layer on the bulk SiCr sub-layer between positions d1 and d2. Positions d1 and d2 are positions of top surfaces of the bulk SiCr sub-layer and Si-rich sub-layer, respectively, in the z-direction. In some embodiments, forming the bulk SiCr sub-layer between positions d0 and d1 during the first co-sputtering operation can include providing a substantially equal amount of power to the Si target and the Cr target. For example, the power provided to the Si target and the Cr target can be between about 100 W and about 1000 W. After forming a targeted thickness of the bulk SiCr sub-layer, the first co-sputtering operation can end and the second co-sputtering operation can begin. In some embodiments, forming the Si-rich sub-layer between d1 and d2 during the second co-sputtering operation can include applying a higher power to the Si target compared to the Cr target. For example, the power provided to the Si target can be between about 300 W and about 1000 W and the power provided to the Cr target can be between about 100 W and about 500 W. The first and second co-sputtering operations can be performed within the same sputtering chamber.

In some embodiments, as shown in FIG. 3E, thin film resistor layer 106 can have a sub-layer with a bulk SiCr composition between d2 and d1, and a Si-rich sub-layer under the sub-layer with the bulk SiCr composition between positions d1 and d0. The sub-layer with the bulk SiCr composition can include about 50 at. % Cr and about 50 at. % Si. In other words, the sub-layer with the bulk composition can have a Si:Cr ratio of 1:1. The Si-rich sub-layer can include about 51 at. % to about 100 at. % Si, such as about 100 at. % Si, and can have a thickness between about 5 Å and about 100 Å.

According to the embodiment shown in FIG. 3E, forming thin film resistor layer 106 between positions d0 and d2 can include (i) a first co-sputtering operation for forming a Si-rich sub-layer between positions d0 and d1 on the ILD layer 104, and (ii) a second co-sputtering operation for forming the Si-rich sub-layer on the bulk SiCr sub-layer between positions d1 and d2. Positions d1 and d2 are positions of top surfaces of the Si-rich sub-layer and bulk SiCr sub-layer, respectively, in the z-direction. In some embodiments, forming the Si-rich sub-layer between positions d0 and d1 during the first co-sputtering operation can include applying a higher power to the Si target compared to the Cr target. For example, the power provided to the Si target can be between about 300 W and about 1000 W and the power provided to the Cr target can be between about 100 W and about 500 W. After forming a targeted thickness of the Si-rich sub-layer, the first co-sputtering operation can end and the second co-sputtering operation can begin. In some embodiments, forming the SiCr bulk sub-layer between d1 and d2 during the second co-sputtering operation can include providing a substantially equal amount of power to the Si target and the Cr target. For example, the power provided to the Si target and the Cr target can be between about 100 W and about 1000 W. The first and second co-sputtering operations can be performed within the same sputtering chamber.

In some embodiments, as shown in FIG. 3F, thin film resistor layer 106 can have a Cr-rich sub-layer between positions d3 and d2, a sub-layer with a bulk SiCr composition (also referred to herein as “bulk SiCr sub-layer”) under the Cr-rich sub-layer between positions d2 and d1, and a Si-rich sub-layer under the sub-layer with the bulk composition between positions d1 and d0. The Cr-rich sub-layer can include about 51 at. % to about 100 at. % Cr, such as about 75 at. % Cr, and can have a thickness between about 5 Å and about 50 Å. The bulk SiCr sub-layer can include about 50 at. % Cr and about 50 at. % Si. In other words, the bulk SiCr sub-layer can have a Si:Cr ratio of 1:1 and a thickness less than about 200 Å. The Si-rich sub-layer can include about 51 at. % to about 100 at. % Si, such as about 100 at. % Si, and can have a thickness between about 5 Å and about 100 Å.

According to the embodiment shown in FIG. 3F, forming thin film resistor layer 106 between positions d0 and d3 can include (i) a first co-sputtering operation for forming the Si-rich sub-layer between positions d0 and d1 on ILD layer 104, (ii) a second co-sputtering operation for forming the bulk SiCr sub-layer on the Si-rich sub-layer between positions d1 and d2, and (iii) a third co-sputtering operation for forming the Cr-rich sub-layer on the bulk SiCr sub-layer between positions d2 and d3. Positions d1, d2 and d3 are positions of top surfaces of the Si-rich sub-layer, bulk SiCr sub-layer, and Cr-rich sub-layer, respectively, in the z-direction. In some embodiments, forming the Si-rich sub-layer between positions d0 and d1 during the first co-sputtering operation can include applying a higher power to the Si target compared to the Cr target. For example, the power provided to the Si target can be between about 300 W and about 1000 W and the power provided to the Cr target can be between about 100 W and about 500 W. After forming a targeted thickness of the Si-rich sub-layer, the first co-sputtering operation can end and the second co-sputtering operation can begin. In some embodiments, forming the bulk SiCr sub-layer between positions d1 and d2 during the second co-sputtering operation can include providing a substantially equal amount of power to the Si target and the Cr target. For example, the power provided to the Si target and the Cr target can be between about 100 W and about 1000 W. After forming a targeted thickness of the SiCr sub-layer, the second co-sputtering operation can end and the third co-sputtering operation can begin. In some embodiments, forming the Cr-rich layer between d2 and d3 during the third co-sputtering operation can include applying a higher power to the Cr target compared to the Si target. For example, the power provided to the Cr target can be between about 250 W and about 1000 W and the power provided to the Si target can be between about 100 W and about 600 W. The first, second, and third co-sputtering operations can be performed within the same sputtering chamber.

In some embodiments, as shown in FIG. 3G, thin film resistor layer 106 can have a Si-rich sub-layer between positions d3 and d2, a sub-layer with a bulk SiCr composition (also referred to herein as “bulk SiCr sub-layer”) under the Si-rich sub-layer between positions d2 and d1, and a Si-rich sub-layer under the sub-layer rich in Si between positions d1 and d0. The Si-rich first sub-layer can include about 51 at. % to about 100 at. % Si, such as about 100 at. % Si, and can have a thickness between about 5 Å and about 40 Å. The second sub-layer with the bulk SiCr composition can include about 50 at. % Cr and about 50 at. % Si. In other words, the second sub-layer with the bulk composition can have a Si:Cr ratio of 1:1. The second sub-layer can have a thickness less than about 200 Å. The Si-rich third sub-layer can include about 51 at. % to about 100 at. % Si, such as about 75 at. % Si, and can have a thickness between about 5 Å and about 100 Å.

According to the embodiment shown in FIG. 3G, forming thin film resistor layer 106 between positions d0 and d3 can include (i) a first co-sputtering operation for forming the Si-rich sub-layer between positions d0 and d1 on ILD layer 104, (ii) a second co-sputtering operation for forming the bulk SiCr sub-layer on the Si-rich sub-layer between positions d1 and d2, and (iii) a third co-sputtering operation for forming the Si-rich sub-layer on the bulk SiCr sub-layer between positions d2 and d3. Positions d1, d2 and d3 are positions of top surfaces of the Si-rich sub-layer, the bulk SiCr sub-layer, and the Si-rich sub-layer, respectively, in the z-direction. In some embodiments, forming the Si-rich sub-layer between positions d0 and d1 during the first co-sputtering operation can include applying a higher power to the Si target compared to the Cr target. For example, the power provided to the Si target can be between about 300 W and about 1000 W and the power provided to the Cr target can be between about 100 W and about 500 W. After forming a targeted thickness of the Si-rich sub-layer, the first co-sputtering operation can end and the second co-sputtering operation can begin. In some embodiments, forming the bulk SiCr sub-layer between positions d1 and d2 during the second co-sputtering operation can include providing a substantially equal amount of power to the Si target and the Cr target. For example, the power provided to the Si target and the Cr target can be between about 100 W and about 1000 W. After forming a targeted thickness of the bulk SiCr sub-layer, the second co-sputtering operation can end and the third co-sputtering operation can begin. In some embodiments, forming the Si-rich sub-layer between d2 and d3 during the third co-sputtering operation can include applying a higher power to the Si target compared to the Cr target. For example, the power provided to the Si target can be between about 300 W and about 1000 W and the power provided to the Cr target can be between about 100 W and about 500 W. The first, second, and third co-sputtering operations can be performed within the same sputtering chamber.

In some embodiments, as shown in FIG. 3H, thin film resistor layer 106 can have a Cr-rich sub-layer between positions d4 and d3, a Si-rich sub-layer under the Cr-rich sub-layer between positions d3 and d2, a sub-layer with a bulk SiCr composition (also referred to herein as “bulk SiCr sub-layer”) under the Si-rich sub-layer between positions d2 and d1, and a Si-rich sub-layer under the bulk SiCr sub-layer between positions d1 and d0. The Cr-rich sub-layer can include about 51 at. % to about 100 at. % Cr, such as about 75 at. % Cr, and can have a thickness between about 5 Å and about 50 Å. The Si-rich sub-layer can include about 51 at. % to about 100 at. % Si, such as about 100 at. % Si, and can have a thickness between about 5 Å and about 40 Å. The bulk SiCr sub-layer can include about 50 at. % Cr and about 50 at. % Si. In other words, the bulk SiCr sub-layer can have a Si:Cr ratio of 1:1 and have a thickness less than about 200 Å. The Si-rich sub-layer can include about 51 at. % to about 100 at. % Si, such as about 100 at. % Si, and can have a thickness between about 5 Å and about 100 Å.

According to the embodiment shown in FIG. 3H, forming thin film resistor layer 106 between positions d0 and d4 can include (i) a first co-sputtering operation for forming a Si-rich sub-layer between positions d0 and d1 on ILD layer 104, (ii) a second co-sputtering operation for forming the bulk SiCr sub-layer on the Si-rich sub-layer between positions d1 and d2, (iii) a third co-sputtering operation for forming the Si-rich sub-layer on the bulk SiCr sub-layer, and (iv) a fourth co-sputtering operation for forming the Cr-rich sub-layer on the Si-rich sub-layer. Positions d1, d2, d3 and d4 are positions of top surfaces of the first Si-rich sub-layer, bulk SiCr sub-layer, Si-rich sub-layer, and Cr-rich sub-layer, respectively, in the z-direction. In some embodiments, forming the Si-rich sub-layer between positions d0 and d1 during the first co-sputtering operation can include applying a higher power to the Si target compared to the Cr target. For example, the power provided to the Si target can be between about 300 W and about 1000 W and the power provided to the Cr target can be between about 100 W and about 500 W. After forming a targeted thickness of the Si-rich sub-layer, the first co-sputtering operation can end and the second co-sputtering operation can begin. In some embodiments, forming the bulk SiCr sub-layer between positions d1 and d2 during the second co-sputtering operation can include providing a substantially equal amount of power to the Si target and the Cr target. For example, the power provided to the Si target and the Cr target can be between about 100 W and about 1000 W. After forming a targeted thickness of the bulk SiCr sub-layer, the second co-sputtering operation can end and the third co-sputtering operation can begin. In some embodiments, forming the Si-rich layer between d2 and d3 during the third co-sputtering operation can include applying a higher power to the Si target compared to the Cr target. For example, the power provided to the Si target can be between about 300 W and about 1000 W and the power provided to the Cr target can be between about 100 W and about 500 W. After forming a targeted thickness of the Si-rich sub-layer, the third co-sputtering operation can end and the fourth co-sputtering operation can begin. In some embodiments, forming the Cr-rich layer between d3 and d4 during the fourth co-sputtering operation can include applying a higher power to the Cr target compared to the Si target. For example, the power provided to the Cr target can be between about 250 W and about 1000 W and the power provided to the Si target can be between about 100 W and about 600 W. The first, second, third, and fourth co-sputtering operations can be performed within the same sputtering chamber. In some embodiments, an interface between different SiCr sub-layers can be a sharp interface with negligible inter-diffusion.

Temperature coefficient of resistance (TCR) is a measure of the ability of a film's sheet resistance to change the least when the temperature of the film is increased and decreased. TCR, which is expressed in parts per million per degrees Celsius (ppm/°C.) and is a function of the film material, film composition and deposition conditions. Referring to FIG. 3I, a Si-rich sub-layer can have a negative TCR (e.g., resistance of the Si-rich sub-layer decreases as temperature increases) and a Cr-rich sub-layer can have a positive TCR (e.g., resistance of the Cr-rich sub-layer increases as temperature increases). Therefore, according to the embodiments shown in FIGS. 3B-3H, thin film resistor layer 106 which includes a combination of Si-rich sub-layers and Cr-rich sub-layers can provide a low variation in resistance over temperature. In other words, TFR 109 using a combination of Si-rich and Cr-rich sub-layers can have a TCR close to zero.

In some embodiments, Si-rich and Cr-rich layers can act as passivation layers to protect the bulk SiCr layer from being affected by the layer below or subsequent processes. The Si-rich layer can inhibit oxidation of bulk SiCr from other processes, e.g. intermetallic dielectric formation, with a preference reaction of Si+O→SiO. In some embodiments, the Cr-rich layer can act as an etch stop layer for dry or wet etching due to its high corrosion resistance and hardness.

In some embodiments, the various co-sputtering operations can be timed operations based on a deposition rate of bulk SiCr, Si-rich SiCr and Cr-rich SiCr, calculated from prior experimentation. In some embodiments, the thickness of the bulk SiCr sub-layer, Si-rich sub-layer and the Cr-rich sub-layer can be measured in-situ during the co-sputtering operations.

In some embodiments, SiCr layer 106 can be deposited by sputtering Si-rich sub-layers and Cr-rich sub-layers in different chambers of a sputtering cluster tool. For example, for depositing a Si-rich sub-layer, substrate 102 can be transferred to a sputtering chamber of a sputtering cluster tool with a Si-rich target. After forming the Si-rich sub-layer, substrate 102 can be transferred to a sputtering chamber with a SiCr target with a bulk composition or a Cr-rich target depending on the preferred composition of thin film resistor layer 106.

Referring to FIG. 3A, capping layer 308 is formed over thin film resistor layer 106. Capping layer 308 prevents oxidation of the underlying thin film resistor layer 106 and promotes adhesion for interconnect structures 116. To prevent oxidation of thin film resistor layer 106, capping layer 308 can be deposited in-situ, without removing substrate 102 from the deposition tool used for depositing thin film resistor layer 106. In some embodiments, capping layer 308 and thin film resistor layer 106 can be deposited within the same chamber of the deposition tool. In some embodiments, capping layer 308 and thin film resistor layer 106 can be deposited in different chambers of a sealed cluster tool, so that substrate 102 is transferred between chambers under vacuum or inert gas conditions, to avoid contamination.

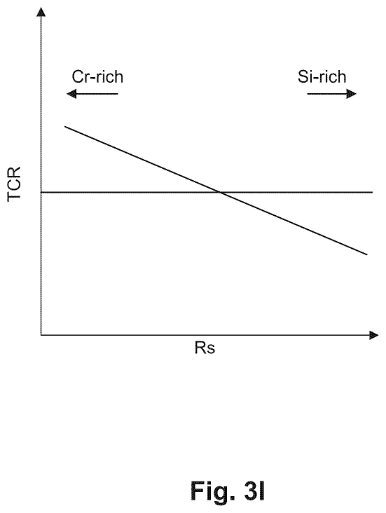

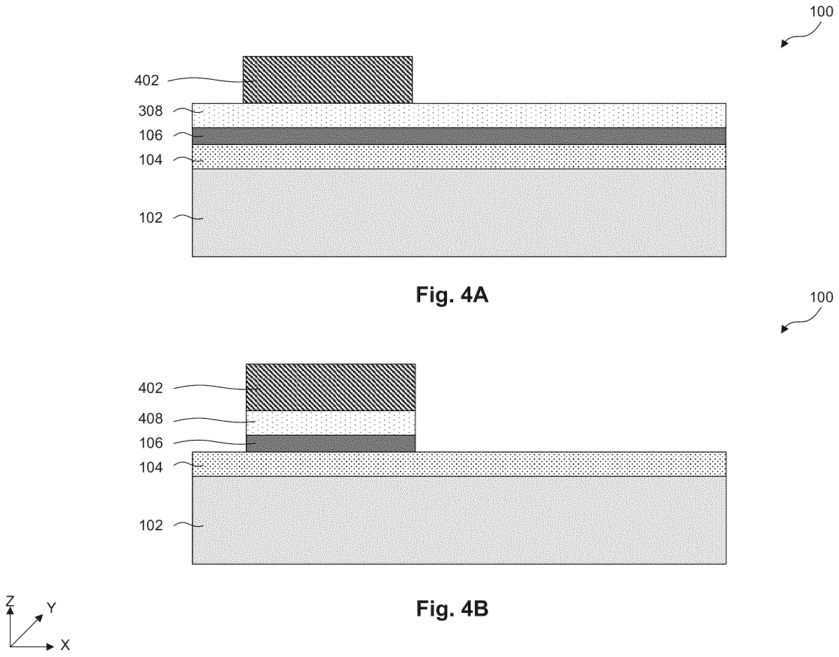

Referring to operation 210 in FIG. 2, the capping layer and thin film resistor layer are patterned and etched to define the TFR. For example, as shown in FIG. 4A, capping layer 308 and thin film resistor layer 106 can be patterned with photoresist layer 402 to define TFR 109. Photoresist layer 402 can cover portions of capping layer 308 and thin film resistor layer 106 where TFR 109 is to be formed. The exposed portions of capping layer 308 and thin film resistor layer 106 can be removed using a suitable etchant to form the structure as shown in FIG. 4B. Thin film resistor layer 106 can be etched by a dry etching process using one or more of Cl₂, CHF₃, BCl₃, or a combination thereof, and additional gases such as one or more of Ar, N₂, O₂, He, or a combination thereof. The dry etching processing can use a power between about 200 W and about 3000 W. Post etching, photoresist layer 402 can be removed.

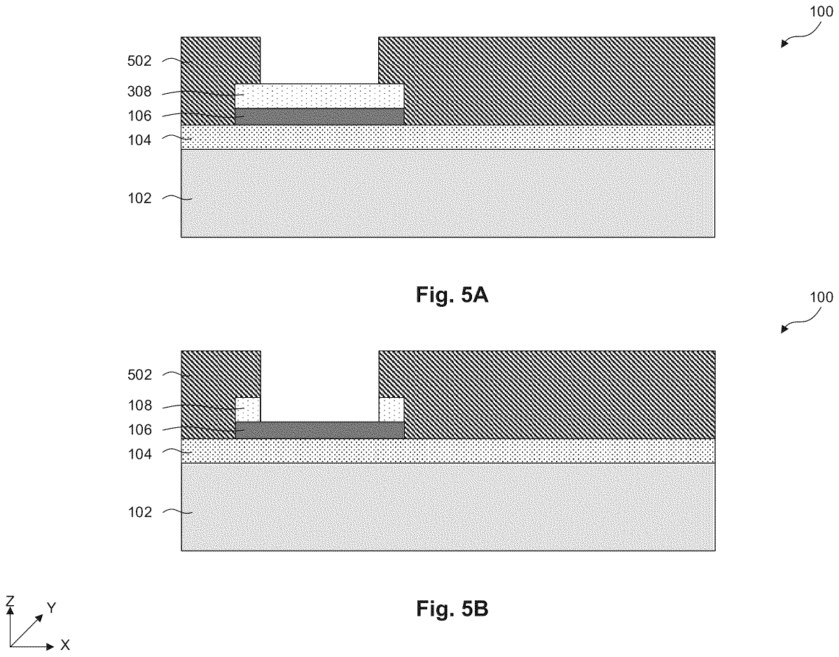

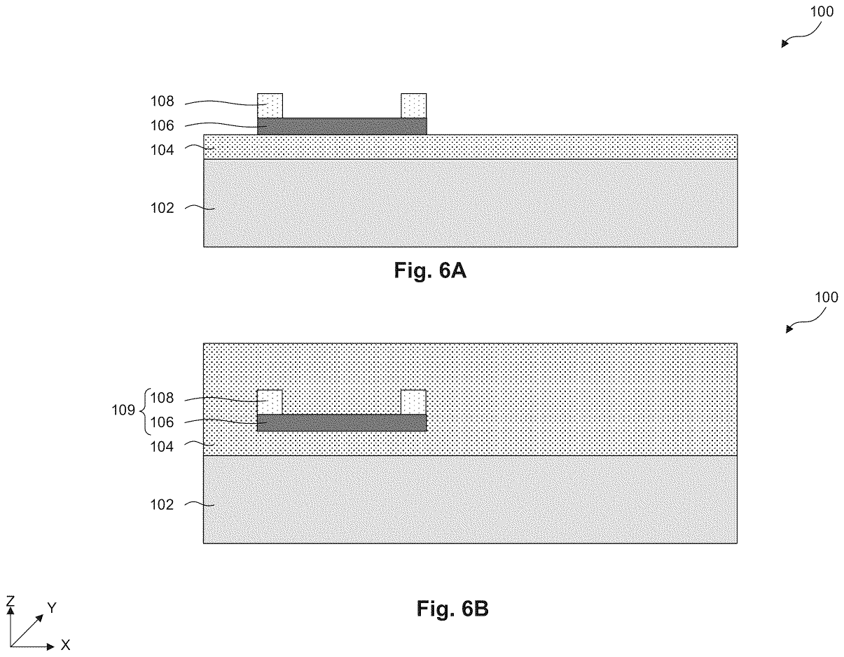

The capping layer is further patterned and etched to form contact regions on two ends of the thin film resistor layer 106. For example, as shown in FIG. 5A, photoresist layer 502 can cover portions of capping layer 308 to define the contact regions. Photoresist layer 502 can cover portions of capping layer 308 where contact regions 108 are to be formed. The exposed capping layer 308 can be etched using a suitable etchant to form the structure shown in FIG. 5B. Post etching photoresist layer 502 can be removed to form the structure shown in FIG. 6A which illustrates TFR 109 that includes thin film resistor layer 106, and contact regions 108.

After forming the TFR, an additional ILD layer can be blanket deposited on the TFR and the underlying ILD layer. For example, as shown in FIG. 6B, an additional ILD layer is blanket deposited to cover TFR 109 and the underlying ILD layer 104. The additional ILD layer can be deposited by a process, such as CVD, PVD, HDPCVD, MOCVD, RPCVD, PECVD, PLD, ALD, any other suitable process, or a combination thereof. In some embodiments, the additional ILD layer is formed of the same material as ILD layer 104 and therefore the ILD layer deposited before and after formation of TFR 109 is referred to herein as “ILD layer 104.”

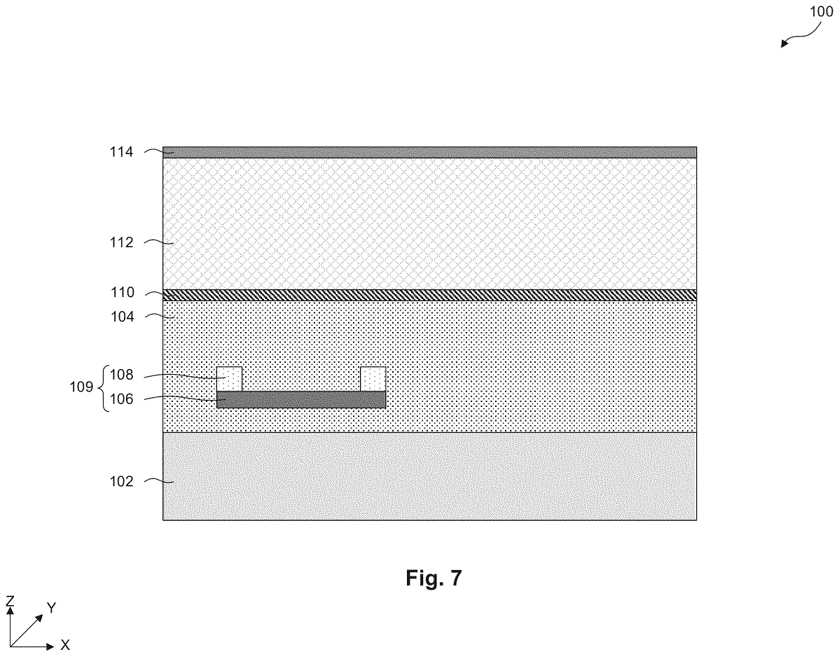

Referring to FIG. 7, in some embodiments, first ESL layer 110 is deposited on the ILD layer 104. First ESL 110 can be blanket deposited on ILD layer 104. First ESL 110 acts as a etch stop layer during subsequent formation of interconnect structures. Therefore, first ESL 110 can be formed of a hard mask material such as silicon nitride (SiₓN_{y}), silicon carbide (SiC), silicon carbon nitride (SiCN), or a combination thereof. First ESL 110 can be deposited using ALD, CVD or sputtering.

Referring to operation 215 in FIG. 2, interconnect structures are formed to contact the contact regions of TFR. According to some embodiments, the process followed to form interconnect structures 116 and 118 is shown in FIGS. 7-12. As shown in FIG. 7, ILD layer 112 can be formed on first ESL 110. ILD layer 112 can be formed of materials similar to those used to form ILD layer 104. ILD layer 112 can be deposited using methods similar to those used to deposit ILD layer 104. Second ESL 114 is subsequently formed on ILD layer 112. Second ESL 114 can function as a hard mask layer for forming openings for interconnect structures 116 and 118. Second ESL 114 cab be formed of SiON, SiN, SiCN, or a combination thereof. Second ESL 114 can be deposited using ALD, CVD or sputtering.

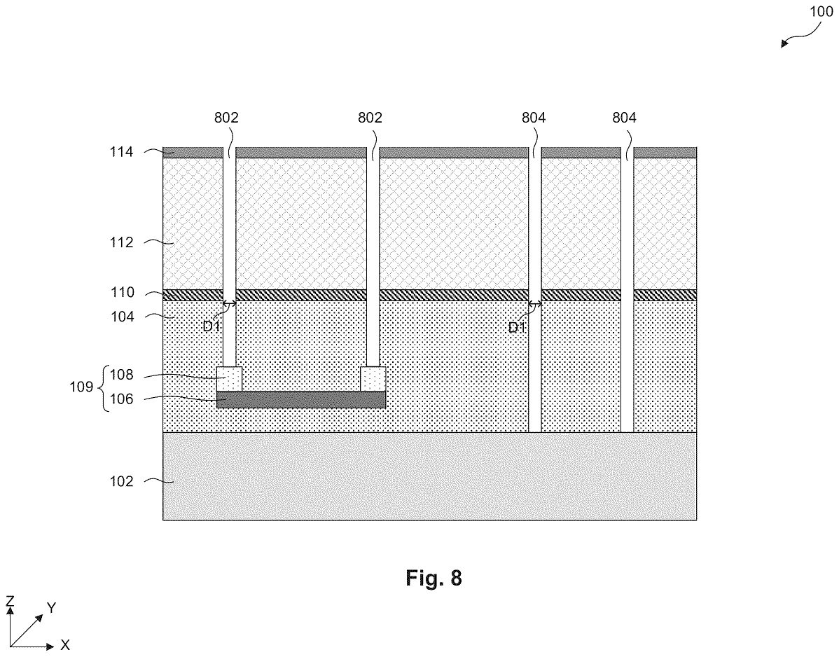

In some embodiments, contact openings are formed by anisotropically etching through the second ESL, the second ILD layer, the first ESL and a portion of the first ILD, as shown in FIG. 8. To form contact openings 802, an opening can be patterned and etched in second ESL 114 (not shown). Subsequently, second ESL 114 can act as a hard mask layer for anisotropically etching through ILD layer 112, first ESL 110 and a portion of ILD layer 104 to form contact openings 802. Dry etching, wet etching, or a combination thereof can be used to anisotropically etch through second ESL 114, ILD layer 112, first ESL 110 and a portion of the first ILD 104. As shown in FIG. 8, contact openings 802 can have a width D1. Contact openings 802 expose contact regions 108 of TFR 109. In some embodiments, openings 804 can be formed by forming corresponding openings in second ESL 114 and anisotropically etching through ILD layer 112, first ESL 110, and the entire thickness of ILD layer 104. Dry etching, wet etching, or a combination thereof can be used to anisotropically etch through second ESL 114, ILD layer 112, first ESL 110 and the entire thickness of the first ILD 104. Contact openings 804 can expose substrate 102. As shown in FIG. 8, contact openings 804 can have a width D1.

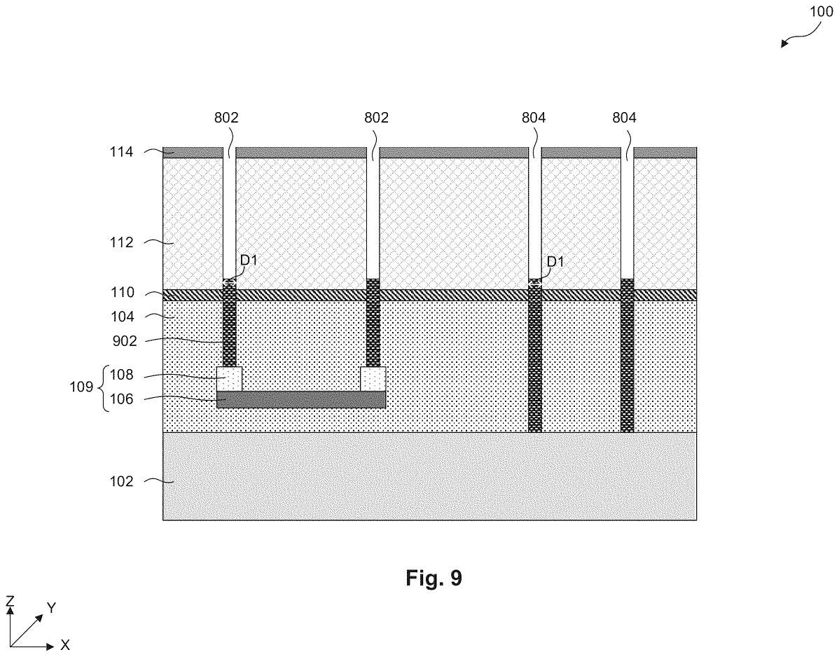

In some embodiments, a portion of contact openings 802 and 804 formed within second metallization layer 120 can be widened by etching ILD layer 112 through contact openings 802 and 804. To protect the exposed contact regions 108 within contact opening 802 and substrate 102 within contact opening 804, contact openings 802 and 804 are partially filled with photoresist layer 902, as shown in FIG. 9. Photoresist layer 902 can be deposited within contact openings 802 and 804 up to about a height of first ESL 110 from substrate 102.

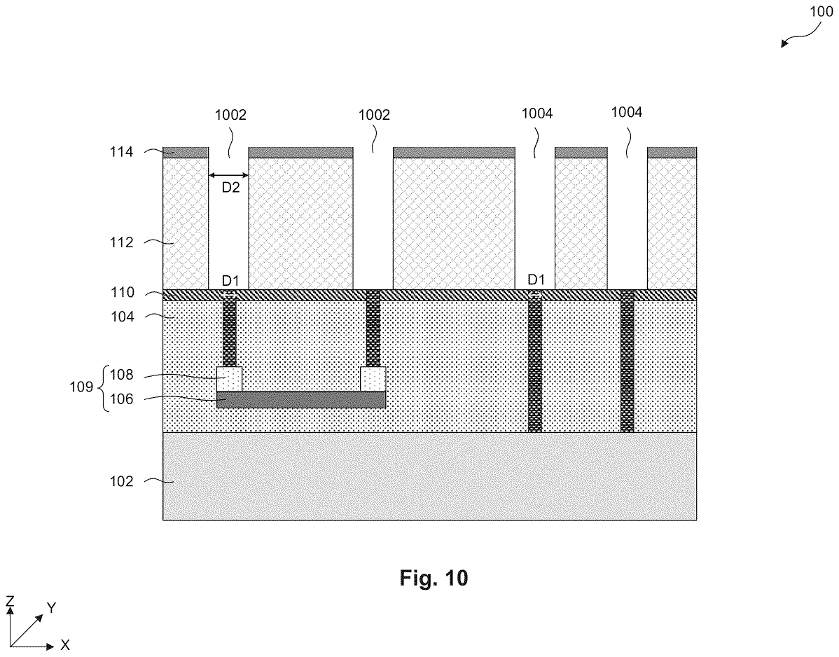

Second ESL 114 can function as a hard mask layer for etching ILD layer 112. Second ESL 114 can be patterned and etched to form an opening with width D2 (not shown). Subsequently, ILD layer 112 within contact openings 802 and 804 can be anisotropically etched. The anistropic etch can be a wet etch, a dry etch or a combination of both. The anisotropic etch etches ILD layer 112 laterally (in a direction parallel to substrate 102) and etches back photoresist layer 902. Photoresist layer 902 and first ESL 110 can function as an etch stop layer during etching of ILD layer 112. As shown in FIG. 10, contact openings 802 and 804 within ILD layer 112 can be widened from width D1 to width D2. As shown in FIG. 10, openings 1002 and 1004 with a width D2 can be formed by etching the exposed portion of ILD layer 112.

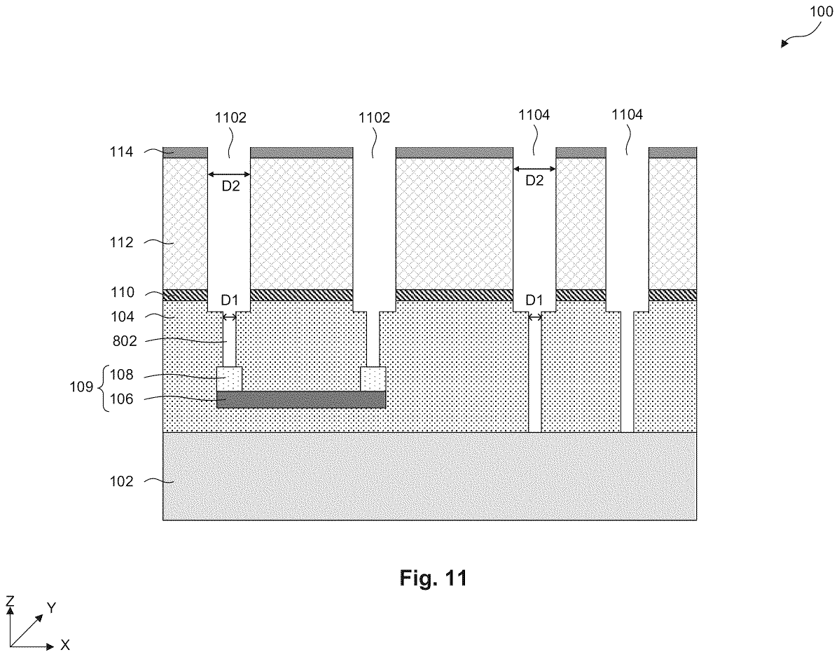

Subsequently, photoresist layer 902 can be removed using photoresist strip or photoresist ash process to form contact openings 1102 and 1104, as shown in FIG. 11. Contact openings 1102 and 1104 can have a width D2 within second metallization layer 120 and width D1 within first metallization layer 111.

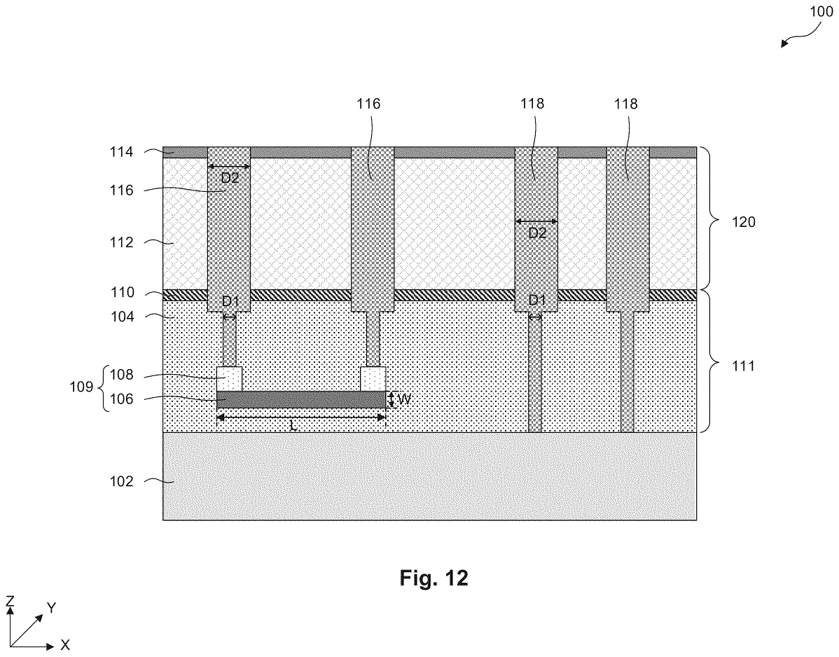

Referring to FIG. 12, in some embodiments, forming interconnect structures 116 and 118 can include (a) depositing a conductive material within contact openings 1102 and 1104, and (b) performing a CMP process on the deposited conductive material to substantially coplanarize top surfaces of the conductive material with a top surface of second ESL 114. In some embodiments, forming interconnect structures 116 and 118 can include (a) depositing a conductive liner layer on sidewall surfaces and a bottom surface of contact openings 1102 and 1104 (not shown), (b) depositing a conductive material on the conductive liner layer to fill contact openings 1102 and 1104, and (c) performing a chemical mechanical polishing (CMP) process on the deposited conductive material and liner layer to substantially coplanarize top surfaces of the conductive material and the liner layer with a top surface of second ESL 114. In some embodiments, a lower portion of interconnect structures 116 and 118 with width D1 can be formed as vias. In some embodiments, an upper portion of interconnect structures 116 and 118 with width D2 can be formed as metal lines running in the Y-direction.

The present disclosure provides a semiconductor device (e.g., semiconductor device 100) that includes a TFR (e.g., TFR 109) that can mitigate deviation of TCR and Rs during fabrication process integration of TFR with the CMOS fabrication process. The present disclosure also provides an example method (e.g., method 200) for fabricating the same. The TFR can include a chromium-based resistor layer (e.g., thin film resistor layer 106). For example, the chromium-based resistor layer can be SiCr. Rather than fabricating a SiCr layer with a uniform Si:Cr ratio across its entire thickness, the SiCr layer can have a composition gradient along its thickness in a direction perpendicular to the substrate. A SiCr layer with a composition gradient can be formed of sub-layers with different SiCr compositions (e.g., according to the embodiments shown in FIG. 3B-3H). An as-deposited graded SiCr layer, can, after being exposed to subsequent CMOS processing operations develop a uniform Si: Cr ratio or a uniform SiCr composition. The sub-layers forming the graded SiCr layer can have (a) a placement along the thickness of the SiCr layer suited to withstand an impact of the CMOS process operation which can be etching, oxidation, thermal annealing, or other operations, and (b) an optimized Si:Cr ratio which after being influenced by the CMOS process operations mentioned above can result in a uniform Si:Cr ratio or a uniform SiCr composition.

In some embodiments, a structure includes a dielectric layer on a substrate, a chromium (Cr)-based resistor layer on the dielectric layer, and contact structures on the Cr-based resistor layer including contact regions on the Cr-based resistor layer and contact structures in contact with the contact regions. The Cr-based resistor layer has a varying Cr composition along a thickness. In some embodiments, a structure includes a first metallization layer including a dielectric layer on a substrate, a silicon chromium (SiCr) layer on the dielectric layer, a contact layer on the SiCr layer, and a first portion of a contact structure in contact with the contact layer. The SiCr layer has a varying silicon composition along a direction perpendicular to the substrate. The structure further includes a second metallization layer including a second portion of the contact structure in contact with the first portion of the contact structure.

In some embodiments, a structure includes a first metallization layer, including a dielectric layer on a substrate, a silicon chromium (SiCr) layer on the dielectric layer, wherein the SiCr layer has a varying silicon composition along a direction perpendicular to the substrate, and a contact layer on the SiCr layer. In some embodiments, a first portion of a contact structure in contact with the contact layer, and a second metallization layer, including a second portion of the contact structure in contact with the first portion of the contact structure.

In some embodiments, a method includes forming a dielectric layer on a substrate, depositing a chromium (Cr)-based resistor layer on the dielectric layer, and forming contact structures on the Cr-based resistor layer including forming contact regions on the Cr-based resistor layer and forming conductive structures in contact with the contact regions. The Cr-based resistor layer comprises a varying Cr composition along a thickness.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a dielectric layer on a substrate;
a chromium (Cr)-based resistor layer on the dielectric layer, wherein the Cr-based resistor layer comprises a varying Cr composition along a thickness in a direction perpendicular to the substrate;
contact regions on the Cr-based resistor layer; and
contact structures in contact with the contact regions.

2. The structure of claim 1, wherein the Cr-based resistor layer is formed of a silicon-chromium (SiCr) layer.

3. The structure of claim 2, wherein the SiCr layer comprises a top portion with a first concentration of Cr and a bottom portion with a second concentration of Cr less than the first concentration.

4. The structure of claim 2, wherein the SiCr layer comprises a top portion with a first concentration of silicon (Si) and a bottom portion with a second concentration of Si less than the first concentration.

5. The structure of claim 2, wherein the SiCr layer comprises:
a first portion with a first concentration of Cr;
a second portion on the first portion with a second concentration of Cr less than the first concentration of Cr; and
a third portion on the second portion with a Cr concentration substantially equal to a concentration of Si.

6. The structure of claim 2, wherein the SiCr layer comprises a top portion with about 50 atomic % Si and a bottom portion with about 51 atomic % to about 100 atomic % Si.

7. The structure of claim 2, wherein the SiCr layer comprises:
a first portion with about 51 atomic % to about 100 atomic % Cr;
a second portion on the first portion with about 50 atomic % Si; and
a third portion on the second portion with about 51 atomic % to about 100 atomic % Si.

8. The structure of claim 2, wherein the SiCr layer comprises:
a first portion with about 51 atomic % to about 100 atomic % Si;
a second portion on the first portion with about 50 atomic % Si; and
a third portion on the second portion with about 51 atomic % to about 100 atomic % Si.

9. The structure of claim 2, wherein the SiCr layer comprises:
a first portion with about 51 atomic % to about 100 atomic % Cr;
a second portion on the first portion with about 51 atomic % to about 100 atomic % Si;
a third portion on the second portion with about 50 atomic % Si; and
a fourth portion on the third portion with about 51 atomic % to about 100 atomic % Si.

10. The structure of claim 1, further comprising a second dielectric layer surrounding the contact structures.

11. A structure, comprising:
a first metallization layer, comprising:
a dielectric layer on a substrate;
a silicon chromium (SiCr) layer on the dielectric layer, wherein the SiCr layer has
a varying silicon composition along a direction perpendicular to the substrate;
a contact layer on the SiCr layer; and
a first portion of a contact structure in contact with the contact layer; and
a second metallization layer, comprising a second portion of the contact structure in contact with the first portion of the contact structure.

12. The structure of claim 11, wherein the first portion of the contact structure has a first width.

13. The structure of claim 12, wherein a width of the second portion of the contact structure is greater than the width of the first portion of the contact structure.

14. The structure of claim 13, wherein the SiCr layer comprises one or more sub-layers with a first concentration of Si and one or more sub-layers with a second concentration of Si different from the first concentration.

15. The structure of claim 11, wherein the SiCr layer comprises a stack formed of a plurality of sub-layers wherein an uppermost sub-layer and a bottom-most sub-layer comprise about 51 atomic % to about 100 atomic % silicon.

16. A method, comprising:
forming a dielectric layer on a substrate;
depositing a chromium (Cr)-based resistor layer on the dielectric layer, wherein the Cr-based resistor layer comprises a varying Cr composition along a thickness in a direction perpendicular to the substrate;
forming contact regions on the Cr-based resistor layer; and
forming conductive structures in contact with the contact regions.

17. The method of claim 16, further comprising depositing the Cr-based resistor layer using a sputtering process.

18. The method of claim 16, wherein depositing the Cr-based resistor layer comprises:
sputter depositing a first sub-layer with a first Cr concentration; and
sputter depositing on the first sub-layer, a second sub-layer with a second Cr concentration different from the first Cr concentration.

19. The method of claim 17, wherein depositing the Cr-based resistor layer comprises varying a power applied to a Cr sputtering target to vary the Cr composition along the thickness of the Cr-based resistor layer.

20. The method of claim 17, further comprising:
depositing a capping layer on the Cr-based resistor layer; and
etching the capping layer to form contact regions on ends of the Cr-based resistor layer.
